(19) United States
(12) Patent Application Publication
(10) Pub. No.: US 2026/0020180 A1
(43) Pub. Date: Jan. 15, 2026

(54) ELECTRONIC DEVICE

(71) Applicant: Acer Incorporated, New Taipei City (TW)

(72) Inventors: Chun-Hung Wen, New Taipei City (TW); Hui-Ping Sun, New Taipei City (TW); Chun-Hsien Chen, New Taipei City (TW)

(73) Assignee: Acer Incorporated, New Taipei City (TW)

(21) Appl. No.: 19/241,365

(22) Filed: Jun. 17, 2025

(30) Foreign Application Priority Data
Jul. 12, 2024 (TW) 113126292

(51) Int. Cl. H05K 7/20; F16C 11/04; G06F 1/20

(52) U.S. Cl. CPC H05K 7/20172; F16C 11/04; G06F 1/203

(57) ABSTRACT

An electronic device including a body, a movable cover, and a fan is provided. A bottom of the body has a groove, and the groove has a fan positioning space. The movable cover is pivotally connected to the bottom of the body and is adapted to close or open the groove. The fan is detachably mounted on the movable cover. The fan is adapted to move synchronously with the movable cover so as to move into the fan positioning space or move out of the fan positioning space.

### CROSS-REFERENCE TO RELATED APPLICATION

This application claims the priority benefit of Taiwan application serial no. 113126292, filed on Jul. 12, 2024. The entirety of the above-mentioned patent application is hereby incorporated by reference herein and made a part of this specification.

### BACKGROUND

### Technical Field

The disclosure relates to an electronic device, and in particular to an electronic device including a fan.

### Description of Related Art

During the operation of a laptop computer, the internal heat sources (e.g., the central processing unit, graphics processing unit, or other electronic elements) of the main body of the laptop computer generate a significant amount of heat. If the heat cannot be quickly dissipated to the external environment, the computing performance of the central processing unit or graphics processing unit may easily decrease due to overheating.

Specifically, for most laptop computers, air-cooled heat dissipation modules are adopted in the main bodies. By dissipating the heat of the heat sources with fans and expelling hot air to the external environment, the rise of the internal temperature of the main body can be prevented. Generally, most fans are fastened and fixed to the circuit board with screws. A user must disassemble the casing of the main body before removing the fans from the circuit board for maintenance, replacement, cleaning, or other operations. Relatively, after completing maintenance, replacement, cleaning, or other operations, the user must reassemble the fans and the casing in sequence. The disassembly and reassembly procedure is not only cumbersome but also time-consuming.

### SUMMARY

The disclosure provides an electronic device to simplify a disassembly procedure, further significantly reducing disassembly time.

The disclosure provides an electronic device, including a body, a movable cover, and a fan. A bottom of the body has a groove, and the groove has a fan positioning space. The movable cover is pivotally connected to the bottom of the body and is adapted to close or open the groove.

The fan is detachably mounted on the movable cover. The fan is adapted to move synchronously with the movable cover so as to move into the fan positioning space or move out of the fan positioning space.

Based on the above, according to the design of mounting the fan on the movable cover, a user may quickly move the fan out of an inside of the body by opening the movable cover so as to perform maintenance, replacement, cleaning, or other operations. Relatively, after completing maintenance, replacement, cleaning, or other operations, the user may quickly mount the fan back into the body by closing the movable cover. As the disassembly procedure is simple and intuitive, disassembly time can be significantly reduced.

To make the features and advantages of the disclosure more comprehensible, several embodiments accompanied with drawings are described in detail as follows.

### BRIEF DESCRIPTION OF THE DRAWINGS

FIG. 1A is a schematic diagram of an electronic device in a first state according to an embodiment of the disclosure.

FIG. 1B is a schematic diagram of the portable electronic device in FIG. 1A transitioning to a second state.

FIG. 1C is an enlarged schematic diagram of a portion 1C in FIG. 1A.

FIG. 1D is an enlarged schematic diagram of a portion 1D in FIG. 1B.

FIG. 1E is a partial cross-sectional schematic diagram along Line 1E-1E in FIG. 1C.

FIG. 2A is a schematic diagram of a fan in FIG. 1B being detached from a body along with a movable cover.

FIG. 2B is a partial cross-sectional schematic diagram along Line 2B-2B in FIG. 2A.

FIG. 2C is a partial cross-sectional schematic diagram along Line 2C-2C in FIG. 2A.

### DESCRIPTION OF THE EMBODIMENTS

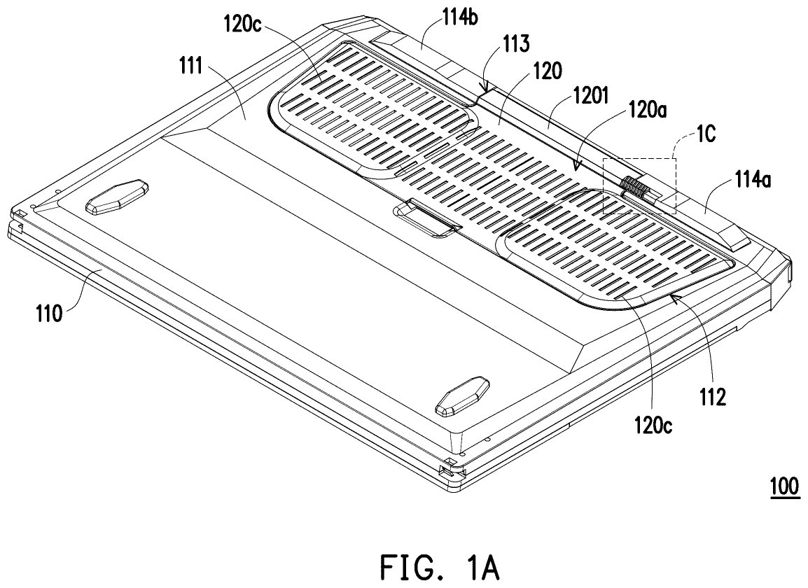

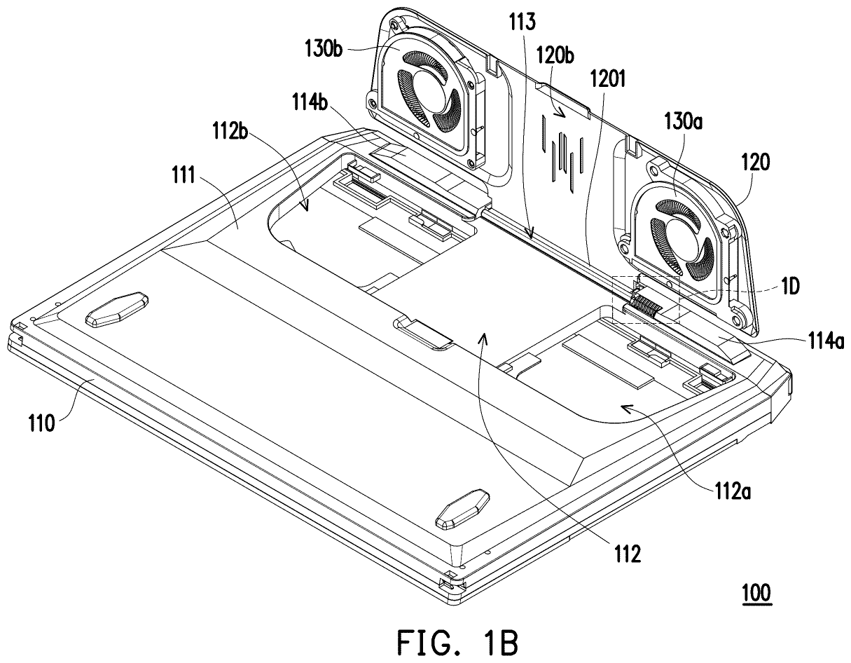

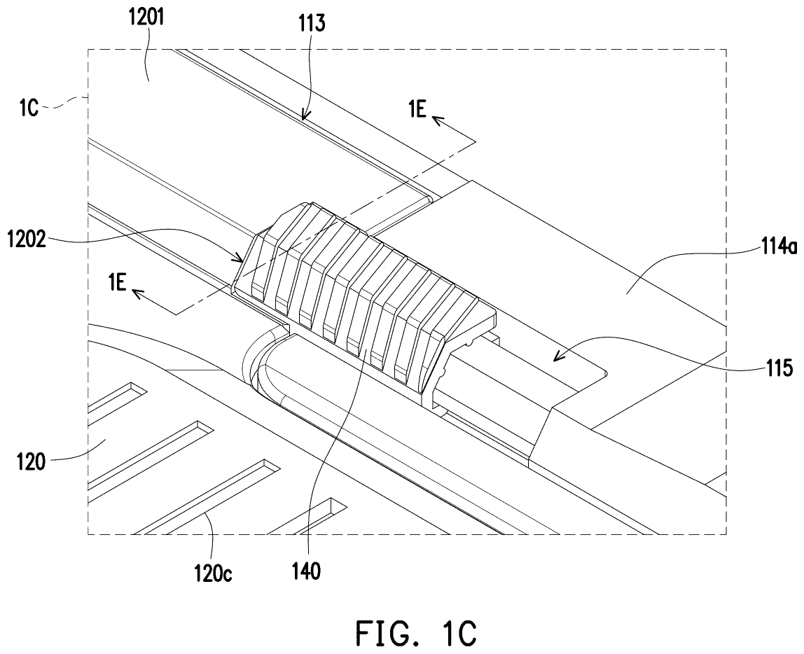

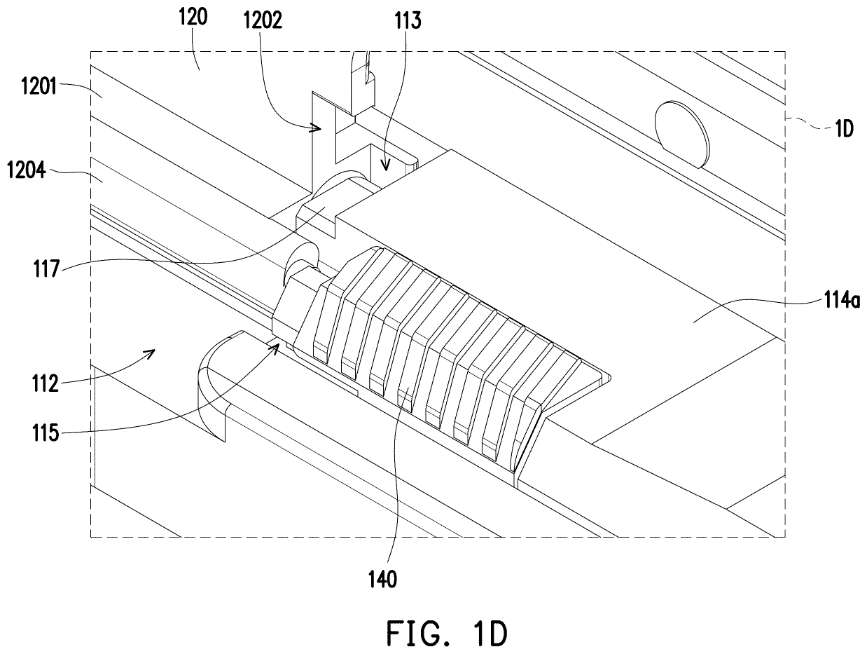

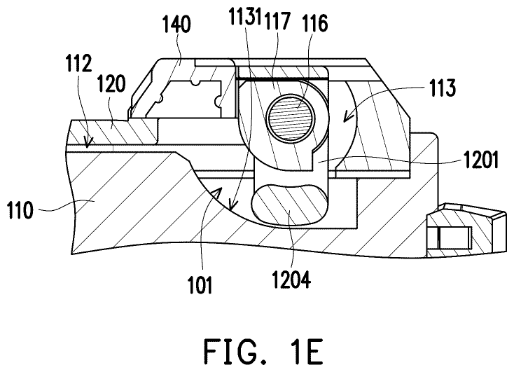

FIG. 1A is a schematic diagram of an electronic device in a first state according to an embodiment of the disclosure. FIG. 1B is a schematic diagram of the portable electronic device in FIG. 1A transitioning to a second state. Please refer to FIGS. 1A and 1B. In this embodiment, an electronic device 100 may be a main body with logical computing capabilities in a laptop computer. The electronic device 100 includes a body 110, a movable cover 120, a first fan 130a, and a second fan 130b. Specifically, the movable cover 120 is pivotally connected to a bottom 111 of the body 110. Thus, the movable cover 120 may rotate relative to the body 110 to close a groove 112 of the bottom 111 or open the groove 112 of the bottom 111. In other words, the movable cover 120 is disposed corresponding to the groove 112, and a geometric outer contour of the movable cover 120 complements or matches a geometric inner contour of the groove 112.

The first fan 130a and the second fan 130b are mounted on the movable cover 120. The groove 112 has a first fan positioning space 112a and a second fan positioning space 112b, adapted to accommodate the first fan 130a and the second fan 130b respectively. A user may exert force on the movable cover 120 so as to rotate and open the movable cover 120 relative to the bottom 111 of the body 110, thereby opening the groove 112. At the same time, the first fan 130a and the second fan 130b move synchronously with the movable cover 120, thus moving out of the first fan positioning space 112a and the second fan positioning space 112b respectively. Relatively, the user may exert force on the movable cover 120 so as to rotate and close the movable cover 120 relative to the bottom 111 of the body 110, thereby closing the groove 112. At the same time, the first fan 130a and the second fan 130b move synchronously with the movable cover 120, thus moving into the first fan positioning space 112a and the second fan positioning space 112b respectively.

Based on the design of mounting the first fan 130a and the second fan 130b on the movable cover 120, the user may quickly move the first fan 130a and the second fan 130b out of an inside of the body 110 by opening the movable cover 120 so as to perform maintenance, replacement, cleaning, or other operations. Relatively, after completing maintenance, replacement, cleaning, or other operations, the user may quickly mount the first fan 130a and the second fan 130b back into the body 110 by closing the movable cover 120. As the disassembly procedure is simple and intuitive, disassembly time can be significantly reduced.

In other embodiments, the number of fans and the number of fan positioning spaces may be increased or decreased according to actual design requirements.

FIG. 1C is an enlarged schematic diagram of a portion 1C in FIG. 1A. FIG. 1D is an enlarged schematic diagram of a portion 1D in FIG. 1B. FIG. 1E is a partial cross-sectional schematic diagram along Line 1E-1E in FIG. 1C. Please refer to FIGS. 1A to 1D. In this embodiment, the bottom 111 of the body 110 is provided with a pivot slot 113 and a body pivoting part. The pivot slot 113 communicates with the groove 112. The pivot slot 113 and the body pivoting part are located on the same side of the groove 112.

The body pivoting part may include a first body pivoting part 114a and a second body pivoting part 114b, wherein the first body pivoting part 114a, the pivot slot 113, and the second body pivoting part 114b are sequentially arranged on the same side of the groove 112, with the pivot slot 113 located between the first body pivoting part 114a and the second body pivoting part 114b. On the other hand, the movable cover 120 includes a movable cover pivoting part 1201. The movable cover pivoting part 1201 is rotatably disposed in the pivot slot 113, and two opposite ends of the movable cover pivoting part 1201 are pivotally connected to the first body pivoting part 114a and the second body pivoting part 114b respectively.

As shown in FIGS. 1A, 1C, and 1E, in this embodiment, the electronic device 100 further includes a switching member 140. The first body pivoting part 114a has a sliding slot 115 communicating with the pivot slot 113, and the movable cover pivoting part 1201 has a notch 1202 disposed corresponding to the sliding slot 115. Specifically, the switching member 140 is slidably disposed in the sliding slot 115. When the movable cover 120 closes the groove 112, the notch 1202 aligns and communicates with the sliding slot 115. At least a part of the switching member 140 may move from the sliding slot 115 into the notch 1202 to press against the movable cover 120. Since the movable cover 120 is locked to the bottom 111 of the body 110 by the switching member 140, the movable cover 120 is prevented from rotating relative to the body 110 arbitrarily.

Relatively, as shown in FIGS. 1B and 1D, the user may move the switching member 140 so that the switching member 140 moves out of the notch 1202, thereby moving the entire switching member 140 back into the sliding slot 115. When the entire switching member 140 moves back into the sliding slot 115, the switching member 140 is separated from the movable cover 120, and the locking relationship between the switching member 140 and the movable cover 120 is released. At this time, the movable cover 120 may rotate relative to the body 110 freely to open the groove 112 of the bottom 111 (as shown in FIG. 1B) or close the groove 112 of the bottom 111 (as shown in FIG. 1A).

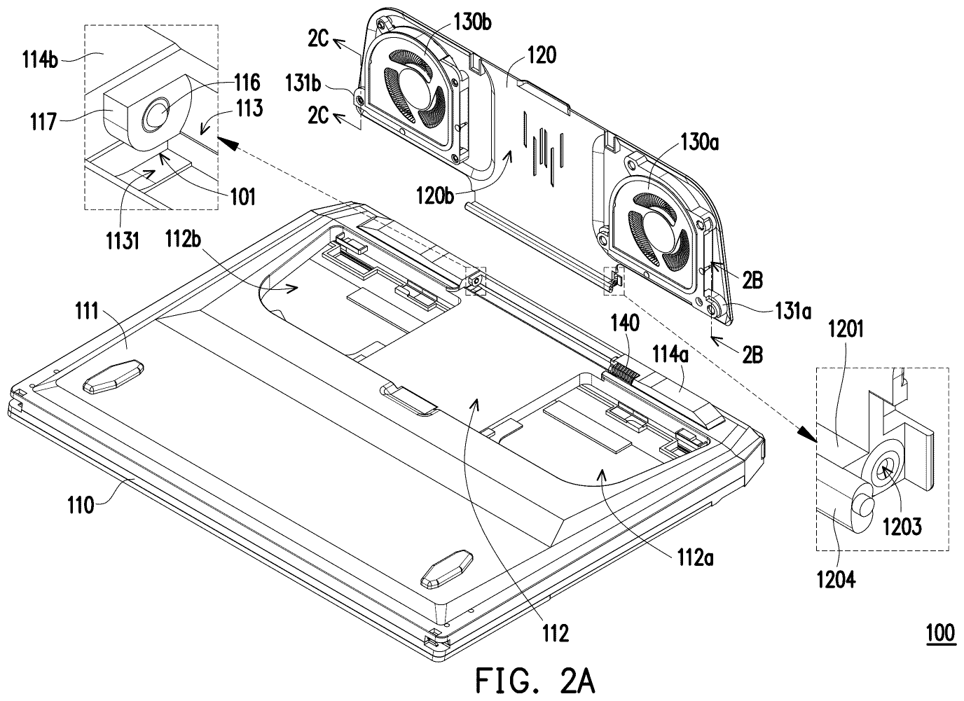

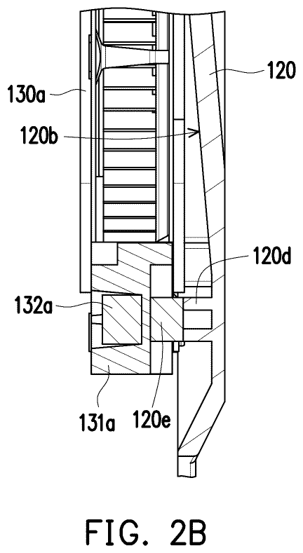

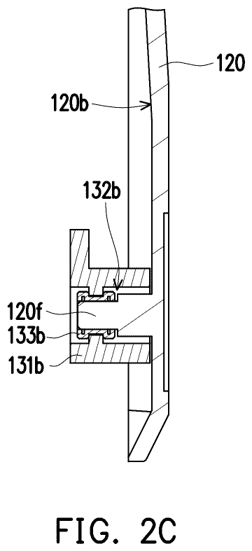

FIG. 2A is a schematic diagram of a fan in FIG. 1B being detached from a body along with a movable cover. FIG. 2B is a partial cross-sectional schematic diagram along Line 2B-2B in FIG. 2A. FIG. 2C is a partial cross-sectional schematic diagram along Line 2C-2C in FIG. 2A. Please refer to FIGS. 1C to 1E and 2A. In this embodiment, both the first body pivoting part 114a and the second body pivoting part 114b are provided with a ball 116 located in the pivot slot 113. Both the two opposite ends of the movable cover pivoting part 1201 are provided with a pivot hole 1203. For example, each ball 116 may be a spring loaded ball and detachably engaged in the corresponding pivot hole 1203.

Specifically, each engaged ball 116 and the corresponding pivot hole 1203 may serve as a rotation fulcrum of the movable cover 120 on the body 110, enabling the movable cover 120 to rotate relative to the body 110 around the rotation fulcrum, thereby opening the groove 112 of the bottom 111 (as shown in FIG. 1B) or closing the groove 112 of the bottom 111 (as shown in FIG. 1A).

As shown in FIGS. 1B, 1D, and 2A, during the process of the movable cover 120 opening the groove 112, once a rotation angle of the movable cover 120 relative to the body 110 is greater than or equal to a set angle (e.g., 90 degrees), the user may exert force to release the engaging relationship between the ball 116 and the corresponding pivot hole 1203, thereby separating the ball 116 from the pivot hole 1203 and detaching the movable cover 120 from the body 110.

During the process of detaching the movable cover 120 from the body 110, the first fan 130a and the second fan 130b are also detached from the body 110 along with the movable cover 120 to facilitate maintenance, replacement, cleaning, or other operations. Relatively, after completing maintenance, replacement, cleaning, or other operations, the user may quickly mount the movable cover 120 back to the body 110 by matching the ball 116 with the corresponding pivot hole 1203.

Please refer to FIGS. 1C to 1E and 2A. In this embodiment, both the first body pivoting part 114a and the second body pivoting part 114b are provided with a positioning protrusion 117 located in the pivot slot 113, and each ball 116 is disposed on the corresponding positioning protrusion 117. On the other hand, a positioning sliding slot 101 is formed between each positioning protrusion 117 and a bottom surface 1131 of the pivot slot 113. The movable cover 120 further includes a sliding guiding part 1204 connected to the movable cover pivoting part 1201, and the sliding guiding part 1204 is slidably disposed in the positioning sliding slot 101.

Further, the sliding guiding part 1204 may substantially slide within the positioning sliding slot 101 around the rotation fulcrum formed by the ball 116 and the corresponding pivot hole 1203, thereby improving the rotational stability of the movable cover 120. For example, the sliding guiding part 1204 has a convex arc surface facing the bottom surface 1131 of the pivot slot 113, and at least a part of the bottom surface 1131 of the pivot slot 113 may be a concave arc surface matching the convex arc surface of the sliding guiding part 1204.

During the process of the movable cover 120 rotating relative to the body 110 and opening the groove 112, the sliding guiding part 1204 slides, within the positioning sliding slot 101, towards an external opening of the positioning sliding slot 101. Before the sliding guiding part 1204 slides to the external opening of the positioning sliding slot 101, the positioning protrusion 117 may provide a limiting effect on the sliding guiding part 1204 within a set angle range (e.g., 90 degrees), preventing the movable cover 120 from accidentally detaching from the body 110.

Please refer to FIGS. 1A, 1B, 2A, and 2B. In this embodiment, the movable cover 120 has an outer surface 120a, an inner surface 120b opposite to the outer surface 120a, and heat dissipation holes 120c penetrating the outer surface 120a and the inner surface 120b. The first fan 130a and the second fan 130b are detachably mounted on the inner surface 120b corresponding to the heat dissipation holes 120c.

As shown in FIGS. 2A and 2B, a first fan positioning part 131a is provided around the first fan 130a, and a second fan positioning part 120d is provided on the inner surface 120b of the movable cover 120 corresponding to the first fan positioning part 131a. The first fan positioning part 131a includes a first magnet 132a, which aligns with the second fan positioning part 120d. Specifically, the second fan positioning part 120d includes a second magnet 120e to generate magnetic attraction force on the first magnet 132a, thereby fixing the first fan 130a on the inner surface 120b of the movable cover 120.

The user may exert force to overcome the magnetic attraction force the second magnet 120e generates to the first magnet 132a to detach the first fan 130a from the movable cover 120 for maintenance, replacement, cleaning, or other operations. Relatively, by matching the second magnet 120e with the first magnet 132a, the user can quickly and accurately mount the first fan 130a back on the inner surface 120b of the movable cover 120.

As shown in FIGS. 2A and 2C, a first fan positioning part 131b is provided around the first fan 130a, and a second fan positioning part 120f is provided on the inner surface 120b of the movable cover 120 corresponding to the first fan positioning part 131b. Specifically, the first fan positioning part 131b has a via 132b and a bushing 133b engaged and fixed in the via 132b, and the second fan positioning part 120f is a protruding post. As shown in FIG. 2C, the protruding post (i.e., the second fan positioning part 120f) is inserted into the via 132b and the bushing 133b to generate frictional resistance force against the bushing 133b, thereby fixing the second fan 130b on the inner surface 120b of the movable cover 120.

The user may exert force to overcome the frictional resistance force the bushing 133b generates against the protruding post (i.e., the second fan positioning part 120f) to detach the second fan 130b from the movable cover 120 for maintenance, replacement, cleaning, or other operations. Relatively, by matching the protruding post (i.e., the second fan positioning part 120f) with the via 132b, the user can quickly and accurately mount the second fan 130b back on the inner surface 120b of the movable cover 120. For example, the bushing 133b may be a rubber bushing or a silicone bushing used to contact or interfere with the protruding post (i.e., the second fan positioning part 120f) inserted into the via 132b, and to absorb vibrations generated during the operation of the second fan 130b.

In summary, according to the design of mounting the fan on the movable cover, a user may quickly move the fan out of an inside of the body by opening the movable cover so as to perform maintenance, replacement, cleaning, or other operations. Relatively, after completing 5 maintenance, replacement, cleaning, or other operations, the user may quickly mount the fan back into the body by closing the movable cover. As the disassembly procedure is simple and intuitive, disassembly time can be significantly reduced. On the other hand, as the fan is detachably fixed to the second fan positioning part, the user may quickly detach the fan from the movable cover so as to perform maintenance, replacement, cleaning, or other operations.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. An electronic device, comprising:
a body, wherein a bottom of the body has a groove, and the groove has a fan positioning space;
a movable cover, pivotally connected to the bottom of the body, and adapted to close or open the groove; and
a fan, detachably mounted on the movable cover, the fan being adapted to move synchronously with the movable cover, such that the fan moves into the fan positioning space or moves out of the fan positioning space.

2. The electronic device according to claim 1, wherein the bottom of the body is provided with a body pivoting part located at one side of the groove, and the movable cover comprises a movable cover pivoting part, the body pivoting part being provided with a ball, the movable cover pivoting part being provided with a pivot hole, wherein the ball is detachably engaged in the pivot hole.

3. The electronic device according to claim 2, wherein the bottom of the body is further provided with a pivot slot communicating with the groove, the pivot slot and the body pivoting part being arranged on a same side of the groove, the movable cover pivoting part being rotatably disposed in the pivot slot.

4. The electronic device according to claim 3, wherein the body pivoting part is further provided with a positioning protrusion located in the pivot slot, and the ball is disposed on the positioning protrusion, the positioning protrusion and a bottom surface of the pivot slot forming a positioning sliding slot in between, wherein the movable cover further comprises a sliding guiding part connected to the movable cover pivoting part, the sliding guiding part being slidably disposed in the positioning sliding slot.

5. The electronic device according to claim 1, wherein the bottom of the body is provided with a pivot slot and a body pivoting part, and the pivot slot communicates with the groove, the pivot slot and the body pivoting part being located on a same side of the groove, wherein the movable cover comprises a movable cover pivoting part, the movable cover pivoting part being rotatably disposed in the pivot slot and being pivoted to the body pivoting part.

6. The electronic device according to claim 5, wherein the body pivoting part has a sliding slot communicating with the pivot slot, and the movable cover pivoting part has a notch disposed corresponding to the sliding slot, the electronic device further comprising a switching member, wherein the switching member is slidably disposed in the sliding slot and adapted to move from the sliding slot into the notch and press against the movable cover, or to move back to the sliding slot from the notch and be separated from the movable cover.

7. The electronic device according to claim 1, wherein the movable cover has an outer surface, an inner surface opposite to the outer surface, and a heat dissipation hole penetrating the outer surface and the inner surface, wherein the fan is detachably mounted on the inner surface corresponding to the heat dissipation hole, a first fan positioning part is disposed around the fan, and the movable cover is provided with a second fan positioning part on the inner surface, the first fan positioning part being aligned with the second fan positioning part and detachably fixed to the second fan positioning part.

8. The electronic device according to claim 7, wherein the first fan positioning part comprises a first magnet, and the second fan positioning part comprises a second magnet to generate a magnetic attraction force on the first magnet.

9. The electronic device according to claim 7, wherein the first fan positioning part has a via and a bushing engaged and fixed in the via, and the second fan positioning part is a protruding post, the protruding post being inserted into the via and the bushing to generate a frictional resistance force against the bushing.

10. The electronic device according to claim 9, wherein the bushing comprises a rubber bushing or a silicone bushing.
